(19) United States
(12) Patent Application Publication
(10) Pub. No.: US 2002/0060582 A1
(43) Pub. Date: May 23, 2002

(54) Leadless solder for use at high and low temperatures

(76) Inventors: Haruyuki Koyama, Tokyo (JP); Ichiro Tano, Tokyo (JP)

Correspondence Address: FLYNN, THIEL, BOUTELL & TANIS, P.C., 2026 Rambling Road, Kalamazoo, MI, 49008-1699, US

(21) Appl. No.: 09/951,668

(22) Filed: Sep. 13, 2001

(30) Foreign Application Priority Data
Sep. 28, 2000 (JP) 2000-295961

(51) Int. Cl. G01R 31/02

(52) U.S. Cl. 324/760

(57) ABSTRACT

A leadless solder for use at high and low temperatures, applicable to a printed circuit board which is used in a test burn-in test is composed of 3 to 3.5 wt. % Ag, 0.3 to 0, 5 wt. % Cu, and balance Sn in order to ensure long term connection reliability of soldered connections even under severe environmental conditions.

### BACKGROUND OF THE INVENTION

1. Field of the Invention

The present invention relates to a leadless solder for use at high and low temperatures, applicable to a printed circuit board, and so forth, enabling the same to be used repeatedly under severe environmental conditions over a long term.

2. Description of the Related Art

As one of methods for testing a semiconductor, there has recently been in widespread use a test burn-in test for measuring characteristics of the semiconductor by placing a printed circuit board with the semiconductor mounted thereon under severe environmental conditions (a continuous high temperature condition, a high temperature/low temperature thermal cycling condition, or so forth). The printed circuit board with the semiconductor mounted thereon, for use in such a semiconductor test, (a test burn-in board: hereinafter referred to as a TBIB) is required to be able to withstand repeated uses under severe environmental conditions over a long term, and to this end, it has been regarded necessary to ensure connection reliability of soldered connections of the printed circuit board on a long term basis.

However, with respect to soldered connections of electronic equipment, and so forth, soldered by use of a common “tin-lead solder”, it has been difficult to ensure long term connection reliability under severe environmental conditions due to degradation and the like of the tin-led solder itself.

Further, with respect to a “tin-silver solder”, which is a common high temperature solder, it has been difficult to ensure long term connection reliability because of, for example, effects of the tin-silver solder on a printed circuit board at the time of automatic soldering (such as loss of Cu plating), degradation and so forth of soldered connections, occurring thereto due to severe environmental conditions.

Also, another solder, the so-called “high strength solder”, with improved connection reliability at high and low temperatures, obtained by adding silver and others to the tin-lead solder, has been put to practical use, however, as shown in Table 1 given hereinafter, significant improvement has not been attained as yet.

Under the circumstances, it is therefore an object of the invention to provide a leadless solder for use at high and low temperatures, capable of ensuring long term connection reliability of soldered connections even under severe environmental conditions.

### SUMMARY OF THE INVENTION

In order to solve the problem described above, in accordance with a first aspect of the invention, there is provided a leadless solder for use at high and low temperatures, composed of 3 to 3.5 wt. % Ag, 0.3 to 0, 5 wt. % Cu, and balance Sn.

The leadless solder for use at high and low temperatures may be used in the case of mounting a SMD.

With these features, the leadless solder for use at high and low temperatures may be used in environments at high and low temperatures.

### BRIEF DESCRIPTION OF THE DRAWINGS

FIG. 1 is a graph showing relationship between Cu content and solution velocity;

FIG. 2 is a graph showing relationship between Cu content and melting temperature;

FIG. 3 is a graph showing relationship between Cu content and diffusion ratio; and

FIG. 4 is a graph showing relationship between Cu content and tensile strength/elongation.

### DESCRIPTION OF THE PREFERRED EMBODIMENTS

There has been conducted a test burn-in test for measuring characteristics of a semiconductor by subjecting a printed board with the semiconductor mounted thereon to severe environmental conditions such as a high temperature/low temperature thermal cycling condition ranging from, for example, −50° C. to 150° C. When mounting components on a printed circuit board to be used under severe environmental conditions such as those of the test described as above, and so forth, an embodiment of a solder according to the invention is put to use.

More specifically, the embodiment of the solder according to the invention is composed of tin (Sn), silver (Ag), and Copper (Cu). The composition ratios of these elements are 3 to 3.5% by weight for Ag, 0.3 to 0.5% by weight for Cu, and balance for Sn.

With the use of the solder of the composition described above, connection reliability over a long term can be ensured even in a range of from a low temperature region to a high temperature region (namely, from −50° C. to 150° C.). In particular, even in the case of mounting a SMD (surface mountable device), where high soldering strength is required, connection reliability can be ensured. In addition, the solder according to the invention does not contain Pb which is regarded favorable from an environmental protection point of view.

### EXAMPLE

The inventor performed analyses on an Sn-Ag eutectic solder (Sn: 96.5 wt. %, Ag: 3.5 wt. %), and obtained analysis results as shown in Table 1 given below. Indicator values in Table 1 represent relative values on the assumption that those for a solder in current use (a common solder) containing 63 wt. % Sn, and 37 wt. % Pb are designated as “1”, indicating that the Sn-Ag eutectic solder is superior to the solder in current use by a factor of n. For comparative purposes, analysis results for a high-strength solder containing 65 wt. % Sn, and 35 wt. % Pb are also shown in Table 1.

TABLE 1

| | environment | | | | | |
|---|---|---|---|---|---|---|
| | comparative indicator values for connection | | | | | |
| | reliability of soldered connections | | | | | |
| | durability | | | Solder connection | | |
| | at high- | | | condition | | environ- |
| | temper- | thermal | | increase | | ment effects |
| class of | ature. | fatigue | connection | in coarse- | diffusion | lead |
| solder | (150° C.) | strength | strength | ness | layer | content |
| Sn—Ag eutectic | 1000 | 1.17 | 1.2 | none | 4 | 0% |
| high-strength | 3 | 1.06 | 1.4 | 4 | 4 | 35% |
| solder | | | | | | |
| current solder | 1 | 1 | 1 | 1 | 1 | 37% |

As shown in Table 1 above, the Sn-Ag eutectic solder was found superior to the solder in current use in all aspects, and furthermore, the Sn-Ag eutectic solder was found superior to the high-strength solder in almost all aspects.

With the Sn-Ag eutectic solder composed of only Sn and Ag, however, there is a concern about loss of Cu plating in through holes of a printed circuit board according as Cu-Sn diffusion proceeds. Accordingly, the inventor conducted researches on such a possibility, and discovered as a result of the researches that the main cause of the loss of the Cu plating was large consumption of Cu, occurring at the time of wave soldering. Thereupon, a hypothesis was built up that addition of a suitable amount of Cu to the Sn-Ag eutectic solder is effective in prevention of consumption of the Cu plating, and the hypothesis was verified.

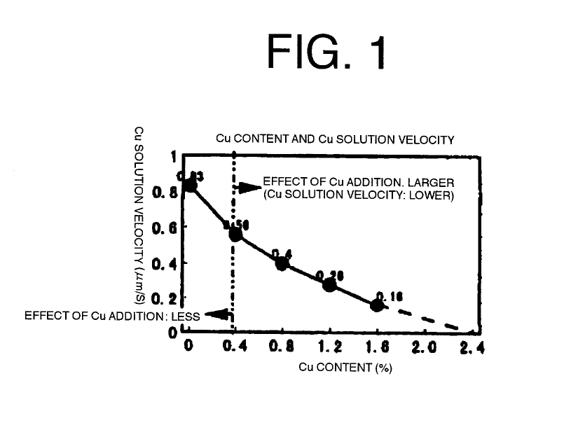

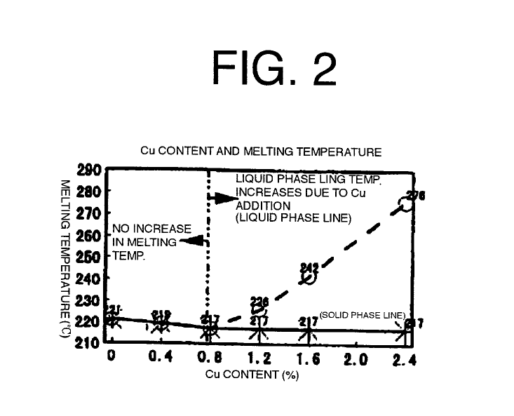

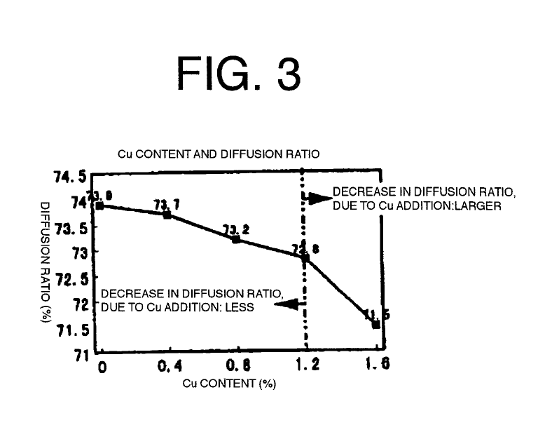

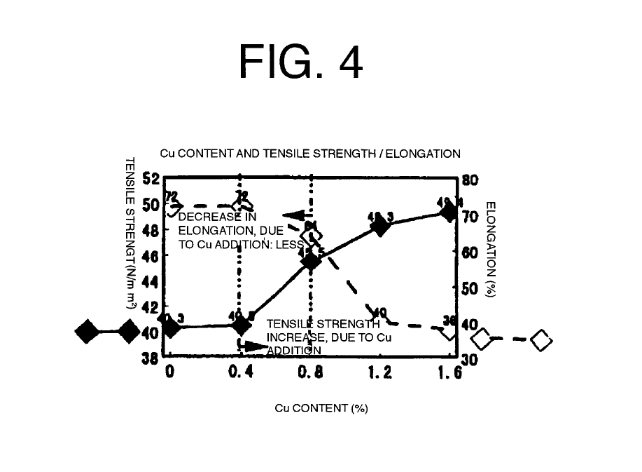

It has been proved from FIGS. 1 to 4 that the addition of Cu is effective. A suitable amount of Cu to be added is in a range of 0.3 to 0.8 wt. %.

In Table 2 given below, the Sn-Ag eutectic solder (before a countermeasure is applied) is compared with a solder obtained by adding 0.4 wt. % of Cu to the Sn-Ag eutectic solder (after the countermeasure is applied). In Table 2, there is shown whether or not a primary jet stream of a wave soldering system exists under a column “primary jet stream”.

TABLE 2

| conditions | | Cu consumption ratio (%) | | | |
|---|---|---|---|---|---|
| class of | primary jet | Minimum | maximum | average | |
| solder | steam | value | value | value | evaluation |
| before | yes | 44.7 | 53.9 | 49.3 | x |
| counter- | no | 13.6 | 20.6 | 16.6 | Δ |
| measure | | | | | |
| (Sn-3.5Ag) | | | | | |
| after | yes | 11.0 | 31.9 | 24.1 | x |
| counter- | no | 5.7 | 17.3 | 9.0 | ◯ |
| measure | | | | | |
| (0.4% Cu | | | | | |
| added) | | | | | |

As shown in Table 2, with respect to the Sn-Ag eutectic solder with 0.4 wt. % of Cu added thereto (after the countermeasure), Cu consumption at the time of wave soldering was reduced to not more than 10% from 50% for the Sn-Ag eutectic solder before the countermeasure. The solder after the countermeasure, with Cu added thereto as above, is the solder according to the invention.

It has been found that use of the solder according to the invention can ensure satisfactory connection quality in a temperature range of −50° C. to 150° C., and a durable period of connection reliability is not less than 5 years.

In accordance with a first aspect of the present invention, connection reliability over a long term can be ensured even in a range of a low temperature region to a high temperature region (namely, from −50° C. to 150° C.). Further, the solder according to the invention does not contain Pb, which is regarded favorable from an environmental protection point of view.

Further, with the solder in accordance with the first aspect of the present invention, connection reliability can be ensured even in the case of mounting a SMD, where high soldering strength is required.

With these features, connection reliability can be ensured even in severe environments such as the test burn-in test, and so forth.

What is claimed is:

1. A leadless solder for use at high and low temperatures, composed of 3 to 3.5 wt. % Ag, 0.3 to 0, 5 wt. % Cu, and balance Sn.

2. A leadless solder for use at high and low temperatures according to claim 1, applicable for use in the case of mounting a SMD.

3. A leadless solder for use at high and low temperatures according to claim 1 or claim 2, applicable for use in environments at high and low temperatures.
